(19) United States
(12) Patent Application Publication
(10) Pub. No.: US 2004/0135232 A1
(43) Pub. Date: Jul. 15, 2004

(54) Semiconductor wafer and method of marking a crystallographic direction on a semiconductor wafer

(76) Inventors: Henry van Bakel, Geldrop (NL); Peter Knapen, Deurne (NL)

Correspondence Address: Allen, Dyer, Doppelt, Milbruth & Gilchrist, P. A., 1401 Citrus Center, 255 South Orange Avenue, Box 3791, Orlando, FL, 32802-3791, US

(21) Appl. No.: 10/339,929

(22) Filed: Jan. 10, 2003

(51) Int. Cl. H01L 23/544

(52) U.S. Cl. 257/620

(57) ABSTRACT

A semiconductor wafer, a method of marking a crystallographic direction on the semiconductor wafer, and a method of processing the marked semiconductor wafer are disclosed. The semiconductor wafer is marked with a scribe line, which in one embodiment is provided with a commercially available scribe tool that is used to cleave III-V type wafers and/or another apparatus that provides a line that is sufficiently narrow to be associated with cleaving the wafer exactly along a predetermined crystallographic plane. Accordingly, the line is also of sufficient narrowness to precisely mark the crystallographic direction. To ensure that the scribe line does not render the marked wafer susceptible to cleavage, the scribe line, or lines, are provided away from the edges of the wafer and with reasonable depths and/or lengths.

### CROSS-REFERENCE TO RELATED APPLICATIONS

Not applicable

Microfiche Appendix

Not applicable

### FIELD OF THE INVENTION

The present invention relates generally to the field of wafers, and in particular to semiconductor wafers, a method of marking the crystallographic direction on a semiconductor wafer, and a method of processing marked semiconductor wafers.

### BACKGROUND OF THE INVENTION

Semiconductor wafers are cut from single-crystal ingots or boules. Since the ingots can be grown in a number of crystal orientations, it is important to be able to differentiate the crystallographic axes of the wafer. In particular, the crystallographic axes and/or corresponding crystal planes may be used to determine where the device features are fabricated on the wafer. For example, in many instances the mirror faces of a laser diode correspond with the crystallographic, or cleave, directions of semiconductor wafers.

Various techniques have been proposed for marking the crystal orientation, typically after the crystallographic axes have been determined with conventional X-ray diffraction analysis. In one of the most common techniques, an orientation flat is formed at an edge of the wafer. In another technique, a notch is engraved and/or cut into an edge of the wafer. In a third technique, a laser mark is put on a front, back side, or edge of the wafer. These techniques are discussed, for example, in U.S. Pat. Nos. 4,418,467, 5,927,263, 6,004,405, 6,420,792, and 6,440,821, hereby incorporated by reference.

Unfortunately, these prior art marking techniques only provide a rough indication of the crystal orientation. For example, in commercially available semiconductor wafers the orientation flat, notch, and/or mark is typically about 0.02-2.0 degrees off the intended crystallographic axis. While this level of accuracy is sufficient for processing some silicon-based devices, it is inadequate for the processing of many others. In particular, the above techniques are inadequate for processing single crystalline wafers used in photolithographic processes requiring a high degree of accuracy and/or precision. Photolithographic processes, which are well-known in the art, involve depositing a photoresist on a wafer, exposing the photoresist to UV radiation through a photolithographic mask that defines the pattern that is to be reproduced, and etching the wafer to form a desired shape or pattern.

Single crystalline III-V wafers, which for example are based on InP, GaAs, GaP, InSb, InAs and GaSb, are examples of semiconductors that are used to design optoelectronic devices that are highly dependent on the accuracy of the photolithographic processes used to create them. In particular, the performance of these devices is typically dependent on the accuracy of alignment between the photolithographic mask and the crystal planes of the single crystalline III-V wafer.

To improve the alignment between the photolithographic mask and the crystal planes, the marked single crystalline III-V wafers are typically cleaved along the required crystal axis prior to the photolithographic process. For example, a small scratch is provided as close as possible to the expected crystallographic axis at the edge of the wafer, near the orientation flat, and the wafer is subsequently bent until the wafer is provided with a freshly cleaved facet parallel to the crystallographic plane {011}. This cleaved surface is used for accurately aligning the photomask to the crystal plane, as is well known to one skilled in the art.

Although the above technique significantly improves the accuracy in alignment, it is associated with a number of disadvantages. First, the scratch used to initiate the cleave damages the wafer and makes it more vulnerable to breakage. Second, the wafer becomes less round, which decreases the homogeneity of subsequent lithographic, expitaxial, and etch processes. Thirdly, the cleave decreases the wafer area, thus reducing the amount of usable wafer.

Alternative techniques to improve the accuracy in alignment and to obviate the cleaving of wafers have recently been proposed. For example, in international publication number WO 01/40876 A1, hereby incorporated by reference, there is disclosed a method and apparatus for aligning a photomask to the crystal plane of a III-V wafer using a novel X-ray diffraction method. In this method and apparatus, the orientation flat(s) on the wafer are not used for alignment purposes, but instead the crystallographic orientation is determined by a measuring tool, including an X-ray source and an X-ray detector, that measures the X-ray count rate of X-ray radiation reflected from a peripheral edge of the wafer. A lithographic tool, which is integrated with the measuring tool, is used to pattern the wafer once the location of the crystal planes are determined. Unfortunately, since the X-ray equipment is integrated into the photoresist exposure equipment, the apparatus is unduly complex and expensive. Moreover, the exposure of the wafer must take place directly after alignment. Since the alignment relies on a calibration with a reference wafer having a cleaved facet, the lithographic tool must be calibrated with each photo-mask change.

In international publication number WO 02/059696 A1, hereby incorporated by reference, another technique that improves the accuracy in alignment and obviates the cleaving of III-V wafers is proposed. The method includes the steps of a) measuring the angular orientation of a peripheral flat, b) measuring a crystallographic orientation of the wafer, c) determining an error angle between the annular orientation of the flat and the crystallographic orientation, and d) rotating the wafer by the determined error angle. Since the error angle can accompany the wafer in subsequent fabrication processing steps, the proposed method advantageously obviates the need to align the photo-mask immediately after the location of the crystallographic plane has been determined. Disadvantageously, the accuracy of the error angle is dependent upon the precision and measurement of the sawed/milled orientation flat.

It is an object of the instant invention to provide a method that improves the accuracy in alignment of photolithographic masks and obviates the cleaving of III-V wafers.

It is a further object of the instant invention to provide a semiconductor wafer, a method of marking the crystallographic direction on the semiconductor wafer, and a method of processing the marked semiconductor wafer that overcomes the disadvantages of the aforementioned prior art.

### SUMMARY OF THE INVENTION

The instant invention provides a semiconductor wafer, a method of marking a crystallographic direction on the semiconductor wafer, and a method of processing the marked semiconductor wafer.

In accordance with the invention the semiconductor wafer is marked with a scribe line. For example, in one embodiment the scribe line is provided with a commercially available scribe tool that is used to scribe III-V type wafers before cleaving. In another embodiment, the line is provided with a laser, or other apparatus, that provides a line that is sufficiently narrow to be associated with cleaving the wafer exactly along a predetermined crystallographic plane. Accordingly, the line is also of sufficient narrowness to precisely mark the crystallographic direction. To ensure that the line does not render the marked wafer susceptible to cleavage, the scribe line, or lines, are preferably provided away from the peripheral edges of the wafer and with reasonable depths and lengths.

In accordance with the invention there is provided a wafer comprising a scribe line on a surface thereof, the scribe line so constructed as to indicate an orientation of a predetermined crystallographic axis of the wafer and such that a stability of the wafer is substantially unaffected.

In accordance with the instant invention there is further provided a method of marking a wafer comprising: positioning the wafer on a chuck; determining the location of a crystallographic axis in the wafer; and marking the direction of the crystallographic axis on a surface of the wafer with at least one scribe line, the at least one scribe line so constructed such that a stability of the wafer is substantially unaffected.

In accordance with the instant invention there is provided a method of marking a wafer comprising: positioning the wafer on a chuck; determining the location of a crystallographic axis in the wafer by irradiating a peripheral edge of the wafer with X-ray radiation; and marking the direction of the crystallographic axis on a surface of the wafer with at least one scribe line in dependence upon the determined location.

In accordance with the instant invention there is further provided a method of processing a wafer comprising: positioning the wafer on an aligner, the wafer having at least one scribe line on a surface thereof, the at least one scribe line being so constructed as to indicate a direction of predetermined crystallographic axis on the wafer; positioning a photomask above the wafer; rotating the aligner relative to the photomask until the scribe line is aligned with the photomask; and irradiating the wafer through the photomask.

In accordance with the instant invention there is further provided an apparatus for marking a wafer comprising: a chuck for positioning the wafer thereon; an X-ray diffractometer coupled to the chuck for determining a location of a crystallographic axis in the wafer; and a wafer scriber coupled to the X-ray diffractometer for marking the direction of the crystallographic axis on a surface of the wafer with at least one scribe line.

### BRIEF DESCRIPTION OF THE DRAWINGS

Exemplary embodiments of the invention will now be described in conjunction with the following drawings wherein like numerals represent like elements, and wherein:

FIG. 1 is a schematic diagram of a commercially available III-V type wafer;

FIG. 2 is a schematic diagram of a III-V wafer according to an embodiment of the instant invention having scribe lines on a surface thereof;

FIG. 3a is a schematic diagram of an apparatus for marking wafers according to an embodiment of the instant invention;

FIG. 3b is a cross-sectional view of FIG. 3a;

FIG. 4a is a schematic diagram of an apparatus for marking wafers according to another embodiment of the instant invention;

FIG. 4b is a cross-sectional view of FIG. 4a; and

FIG. 5 is a flow diagram illustrating a method of processing a marked wafer according to an embodiment of the instant invention.

### DETAILED DESCRIPTION OF THE PREFERRED EMBODIMENTS

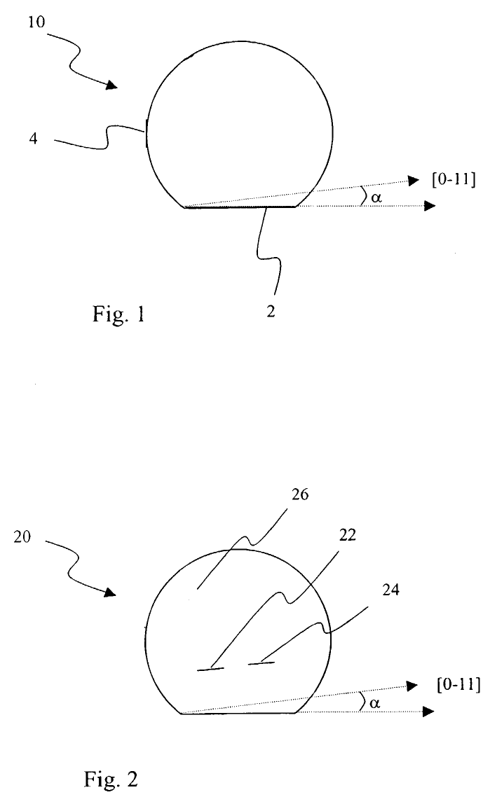

Referring to FIG. 1 there is shown a commercially available III-V semiconductor wafer 10 having a primary flat 2 and a secondary flat 4. The primary 2 and secondary 4 flats are sawed or milled facets designed to show the general crystallographic orientation of the wafer 10. In particular, the primary flat 2 is disposed along the [0-11] crystallographic axis, with a deviation angle, α, which is typically in the order of 0.02 to 0.2 degrees. The secondary flat 4, which is necessary because the III-V crystal does not have four-fold symmetry, is typically perpendicular to the primary flat 2, plus or minus about five degrees.

According to an embodiment of the instant invention, the wafer 10 illustrated in FIG. 1 is marked with a scribe line, or lines. The purpose of the scribe line(s) is to indicate the crystallographic orientation of the III-V crystal with a high degree of accuracy. Although scribe lines have been traditionally only used to weaken wafers so that they can be cleaved, it is presently shown that the scribe line(s) can be constructed and/or positioned such that they do not significantly affect the integrity and/or stability of the wafer.

Referring to FIG. 2, a III-V semiconductor wafer 20 in accordance with the instant invention, is provided with first 22 and second 24 scribe lines on an upper surface 26 of the wafer in the direction of the <011> crystallographic axis. Preferably the scribe lines are formed such that they do not reach the edge of the wafer, where they are more likely to make the wafer prone to damage and/or cleavage. For example, lines formed at least 2-5 mm from the peripheral edge of the wafer generally accomplish this requirement. It is further preferred, that the scribe lines have a length and/or depth selected such that they do not compromise the integrity of the wafer to a significant extent.

Advantageously, the (0-1-1) crystal plane, and hence the position of the scribe lines, is determined by X-ray analysis rather than cleaving the wafer. X-ray diffraction techniques for determining wafer crystal orientation are non-invasive (the X-rays typically only penetrate the sample to a depth of about 10 μm) and are performed rapidly. X-ray diffraction techniques are typically based on the Bragg Law:

2·dₕₖₗ·sin θₙ=nλ

where n is the order of diffraction, λ is the wavelength of the monochromatic X-ray radiation, θₙ is the glancing angle, and dₕₖₗ is the spacing between the {hkl} planes, the latter of which are defined with Miller indices. The X-ray diffraction principle, which is well known in the art, is not discussed further. The X-ray diffraction technique used according to the instant invention measures the scattered radiated from the edge of the wafer, and hence provides a very steep reflection angle that results in high precision.

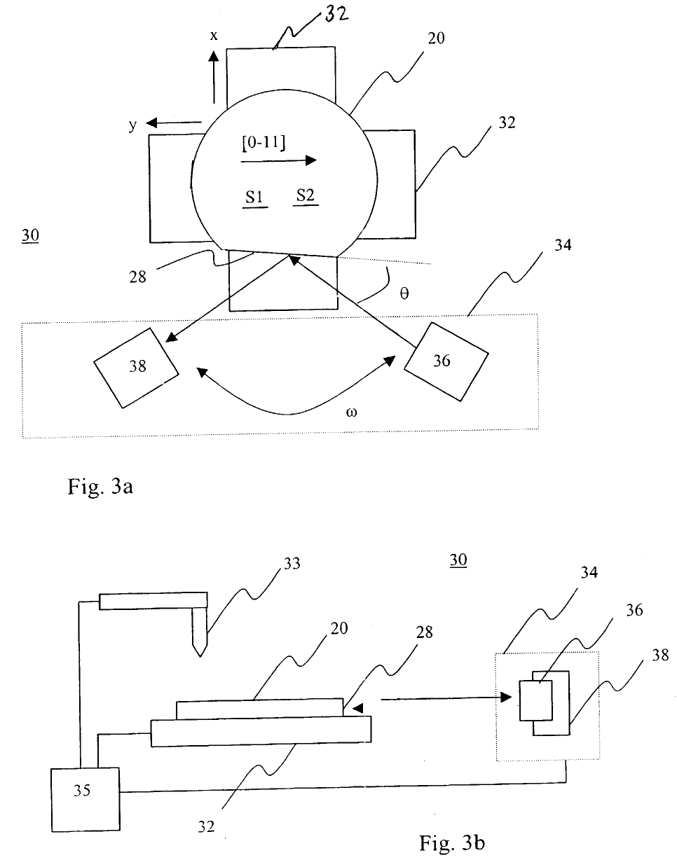

Referring to FIGS. 3a and 3b there is shown an apparatus designed for producing the wafer illustrated in FIG. 2. The apparatus 30 includes a wafer chuck 32 for supporting the wafer 20 and an X-ray diffractometer 34 for determining the position of the (0-1-1) crystal plane. The X-ray diffractometer 34 includes an X-ray radiation source 36 and an X-ray radiation detector 38. Preferably, the X-ray source 36 includes a collimator and a monochromating crystal, as for example, found in commercially available double crystal diffractometers. The wafer chuck 32 is movable and/or rotatable within the plane containing the chuck 32, the X-ray source 36, and the X-ray detector 38. Similarly, the X-ray detector 38 is movable. The apparatus 30 further includes a scriber 33 (not shown in FIG. 3a) mounted above the wafer chuck 32 in a fixed relationship to the X-ray diffractometer 34. For example, in one embodiment the scriber 33 is mounted on the X-ray diffractometer. Preferably, the scriber 33 is a wafer scriber, such as a diamond-tipped scriber, which is typically used in wafer cleaving processes. Alternatively, the scriber 33 is a laser scriber.

Notably, the orientation flat is shown oriented towards the X-ray source in FIGS. 3a and 3b for exemplary purposes only. It is also possible, and in many instances desirable, to mount the wafer 20 such that a round edge of the wafer is irradiated with the X-ray source 36. This means that with the present invention indication of a crystallographic direction with scribe lines of completely circular wafers can be executed.

In operation, the X-ray source 36 irradiates a peripheral edge of wafer 20 with a monochromatic X-ray beam. Simultaneously, the X-ray detector 38 is rotated around the chuck with the wafer 20 such that it tracks and measures the Bragg-reflection scattered from the edge 28 of the wafer as a result of the three dimensional periodicity of the crystal lattice. In particular, the orientation of the crystal planes is found from the rocking curve, which is a plot of diffracted X-ray intensity measured while scanning through a range of θ (or 2θ). The maximum X-ray count detected during the X-ray probe corresponds to the theoretical Bragg position, which in an embodiment using an InP wafer is at ω=21.7912 degrees for the (0-2-2) crystal plane. Once the position of the crystallographic plane (0-1-1) is determined, the chuck 32 moves to the position calculated with the processor 35 so that the scribe tool 33 can produce one or more scribe lines (S1 and S2) along the <011> direction to serve as an indication of its position.

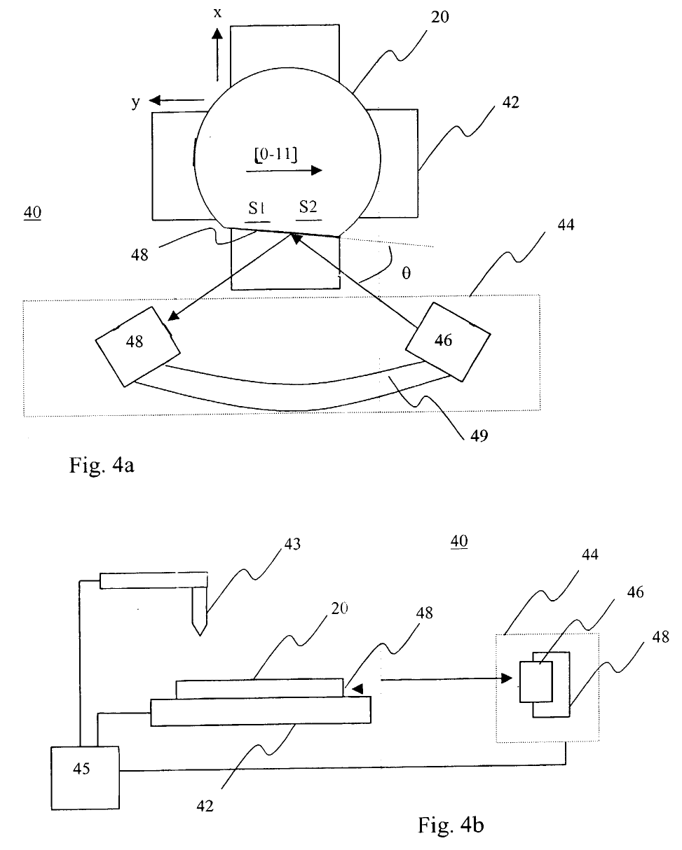

Referring to FIGS. 4a and 4b there is shown an apparatus in accordance with another embodiment of the instant invention for producing the wafer illustrated in FIG. 2. The apparatus 40 includes a wafer chuck 42 for supporting the wafer 20 and an X-ray diffractometer 44 for determining the position of the (0-1-1) crystal plane. The X-ray diffractometer 44 includes an X-ray radiation source 46 and an X-ray radiation detector 48, both of which are mounted on arcuate track 49. The apparatus 40 further includes a scriber 43 (not shown in FIG. 4a) mounted above the wafer chuck 42 in a fixed relationship to the X-ray diffractometer 44. For example, in one embodiment the scriber 43 is mounted on the X-ray diffractometer 44. Preferably, the scriber 43 is a wafer scriber, such as a diamond-tipped scriber, which is typically used in wafer cleaving processes. Alternatively, the scriber 43 is a laser scriber.

Notably, the orientation flat is shown oriented towards the X-ray source in FIGS. 4a and 4b for exemplary purposes only. It is also possible, and in many instances desirable, to mount the wafer 20 such that a round edge of the wafer is irradiated with the X-ray source 46. This means that with the present invention indication of a crystallographic direction with scribe lines of completely circular wafers can be executed.

In operation, the X-ray source 46 irradiates the wafer 20 with a monochromatic X-ray beam as the chuck 42 rotates such that a peripheral edge 28 of the wafer is probed with the X-ray radiation. Simultaneously, the X-ray detector 48 moves along the arcuate track and measures the Bragg-reflection diffracted from the edge 28 of the wafer. Although it is not possible to directly measure the crystal orientation relative to the motor axes of the diffractometer 48, the orientation of the crystal planes relative to the incident X-ray beam of radiation is easily determined. In particular, the maximum X-ray count detected during the X-ray probe corresponding to the theoretical Bragg position is determined, which in one embodiment is at ω=21.7912 degrees for the (0-2-2) crystal plane. Once the position of the crystallographic plane (0-1-1) is determined, the scribe tool 43 produces one or more scribe lines (S1 and S2) along the [0-11] direction to serve as an indication of its position. In particular, the feedback corresponding to the position of the chuck 42 when the maximum X-ray counted detected by the X-ray detector 48 is provided to the processor 45, which calculates the coordinates of the [0-11] crystallographic direction and provides directions to the chuck 42.

Preferably, the scribe tool used to mark the wafer in the aforementioned embodiments produces a line that does not significantly affect the integrity and/or stability of the wafer, as discussed above with respect to FIG. 2. For example, 100-500 μm long scribe lines having depths of approximately 2-4 μm and positioned 15-20 mm apart adjacent the orientation flat have been found not increase wafer breakage in 2 inch, 350 μm thick InP wafers. Of course, scribe lines having significantly greater depth (e.g., greater than 100 μm) are also feasible depending on the position and length of the line(s).

It is further preferred that the scribe tool used to mark the wafer produces a line that is narrow enough to precisely indicate the crystallographic orientation of the crystal and to provide adequate accuracy during a subsequent alignment. For example, scribe lines with widths varying from approximately 1.5-6 μm have been used to achieve accuracy in alignment of better than ½ minute of arc. Of course, any scribe line having a width that is narrow enough to be associated with wafer cleaving is also within the scope of the instant invention. Notably, scribe lines are significantly narrower than prior art laser lines used to mark the course orientation of wafers, which typically have widths greater than 50 μm.

Advantageously, the wafer produced by the above technique remains complete i.e., the original sawed flat remains a part of the wafer and no part of the wafer is cleaved. Accordingly, the wafer is more robust and is less vulnerable to damage during normal handling. The complete marked wafer also possesses a larger surface area, which increases the yield of qualified chips per wafer, and is more round, which increases the homogeneity of subsequent lithographic and/or etch processes. Since this method does not rely upon the sawed/milled facet, it is also applicable to completely round wafers that do not possess course orientation flats, notches, and/or marks. Furthermore, the instant method is not limited to III-V semiconductor wafers, but is also applicable to other single crystalline substrates and/or wafers, such as silicon and II-VI semiconductors, which need to be aligned to a photolithographic mask with great accuracy.

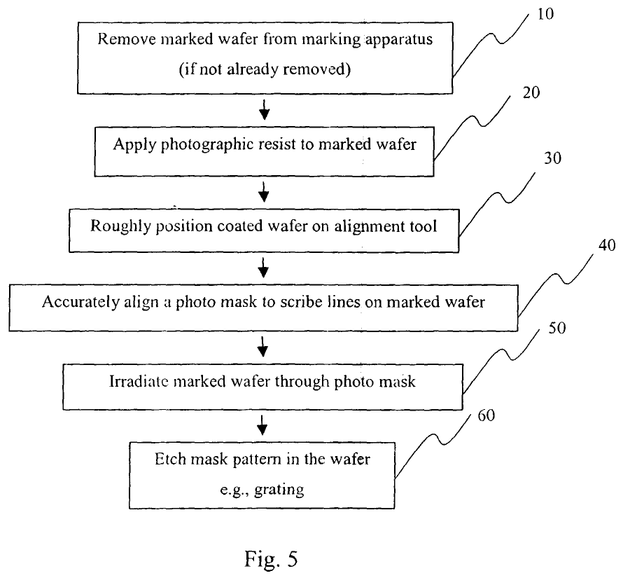

Wafers according to the above techniques may be further processed according to various methods. For example, in one embodiment a III-V semiconductor wafer marked with one of the aforementioned techniques is processed to fabricate a grating that is used in a distributed feedback (DFB) laser. Referring to FIG. 5, this process is illustrated with a flow diagram. In the first step 50, the wafer marked with the apparatus illustrated in FIGS. 3a and 3b is removed from the chuck 34. In a second step 52, the marked wafer is coated with a transparent photoresist. In a third step 54, the wafer is placed on an alignment substrate of a photolithographic tool. In a fourth step 56, the scribe lines are aligned with an overlaying photolithographic mask using a microscope. In a fifth step 58, the wafer is exposed to UV radiation through the photomask to form, for example, a grating. In a sixth step 60, the wafer is etched and the photoresist is removed. Optionally, additional feature layers are registered with respect to the first feature layer.

Advantageously, this method of processing III-V wafers is accurate, precise and does not require that the wafer be cleaved to determine the crystallographic axes. Furthermore, this method does not require that the crystallographic axes be found immediately before the processing. Accordingly, this method allows the processing of wafers taken from a stockpiled supply of marked wafers. Since this method reduces the processing time, efforts, and costs of processing III-V semiconductor wafers, relative to prior art methods, it is anticipated that it has great potential for the fabrication of semiconductor lasers.

Of course, the above-described embodiments of the invention are intended to be examples of the present invention and numerous modifications, variations, and adaptations may be made to the particular embodiments of the invention, without departing from the spirit and scope of the invention.

What is claimed is:

1. A wafer comprising a scribe line on a surface thereof, the scribe line so constructed as to indicate an orientation of a predetermined crystallographic axis of the wafer and such that a stability of the wafer is substantially unaffected.

2. A wafer according to claim 1, wherein the scribe line is disposed parallel to the predetermined crystallographic axis.

3. A wafer according to claim 2, wherein the scribe line is disposed away from a peripheral edge of the wafer.

4. A wafer according to claim 1, wherein the scribe line does not contact a peripheral edge of the wafer.

5. A wafer according to claim 1, wherein the wafer comprises a single crystalline III-V wafer.

6. A method of marking a wafer comprising:
positioning the wafer on a chuck;
determining the location of a crystallographic axis in the wafer; and
marking the direction of the crystallographic axis on a surface of the wafer with at least one scribe line, the at least one scribe line so constructed such that a stability of the wafer is substantially unaffected.

7. A method according to claim 6, wherein the step of determining the location of the predetermined crystallographic axis comprises an X-ray diffraction analysis.

8. A method according to claim 7, wherein the X-ray diffraction analysis comprises the steps of:
irradiating a peripheral edge of the wafer with X-ray radiation; and
detecting the X-ray radiation diffracted from the edge of the wafer.

9. A method according to claim 6, wherein the step of marking the direction of the crystallographic axis includes scratching the surface of the wafer.

10. A method according to claim 6, wherein the step of marking the direction of the crystallographic axis includes using a laser scriber.

11. A method according to claim 6, wherein the step of marking the direction of the crystallographic axis includes using a diamond-tipped scriber.

12. A method according to claim 6, wherein the step of marking the direction of the crystallographic axis includes positioning the at least one scribe line parallel to the crystallographic axis.

13. A method according to claim 8, wherein the step of marking the direction of the crystallographic axis includes positioning the at least one scribe line parallel to the crystallographic axis.

14. A method according to claim 6, wherein the step of marking the direction of the crystallographic axis includes positioning the at least one scribe line away from a peripheral edge of the wafer.

15. A method according to claim 8, wherein the step of marking the direction of the crystallographic axis includes positioning the at least one scribe line away from a peripheral edge of the wafer.

16. A method of marking a wafer comprising:
positioning the wafer on a chuck;
determining the location of a crystallographic axis in the wafer by irradiating a peripheral edge of the wafer with X-ray radiation; and
marking the direction of the crystallographic axis on a surface of the wafer with at least one scribe line in dependence upon the determined location.

17. A method of processing a wafer comprising:
positioning the wafer on an aligner, the wafer having at least one scribe line on a surface thereof, the at least one scribe line being so constructed as to indicate a direction of a predetermined crystallographic axis on the wafer;
positioning a photomask above the wafer;
rotating the aligner relative to the photomask until the scribe line is aligned with the photomask; and
irradiating the wafer through the photomask.

18. A method according to claim 17, comprising the step of depositing a photoresist on the wafer prior to the step of positioning the wafer on the aligner.

19. An apparatus for marking a wafer comprising:
a chuck for positioning the wafer thereon;
an X-ray diffractometer coupled to the chuck for determining a location of a crystallographic axis in the wafer; and
a wafer scriber coupled to the X-ray diffractometer for marking the direction of the crystallographic axis on a surface of the wafer with at least one scribe line.

20. An apparatus according to claim 19, comprising a processor coupled to the chuck, the X-ray diffractometer, and the wafer scriber.
